(19) United States
(12) Patent Application Publication
(10) Pub. No.: US 2006/0198958 A1
(43) Pub. Date: Sep. 7, 2006

(54) Methods for producing silicon nitride films by vapor-phase growth

(76) Inventors: Christian Dussarrat, Ibaraki (JP); Jean-Marc Girard, Paris (FR); Takako Kimura, Tsukuba (JP); Naoki Tamaoki, Tokyo (JP); Yuusuke Sato, Tokyo (JP)

Correspondence Address: AIR LIQUIDE, 2700 POST OAK BOULEVARD, SUITE 1800, HOUSTON, TX, 77056, US

(21) Appl. No.: 10/553,573

(22) PCT Filed: Apr. 8, 2004
(86) PCT No.: PCT/IB04/01346

§ 371 Date: Oct. 17, 2005

(51) Int. Cl. C23C 16/34

(52) U.S. Cl. 427/255.394

(57) ABSTRACT

Methods for the production of silicon nitride films by vapor-phase growth. A hydrazine gas and at least one precursor gas are fed into a reaction chamber containing a substrate. The precursor gas is either a trisilylamine gas or a silylhydrazine gas. A silicone nitride film is formed through the reaction of the hydrazine gas and the precursor gas.

This invention relates to methods for producing silicon nitride films and more particularly relates to methods for producing silicon nitride films by vapor-phase growth, such as chemical vapor deposition (CVD).

Silicon nitride films have excellent barrier properties and an excellent oxidation resistance and as a consequence are used in the fabrication of microelectronic devices, for example, as an etch-stop layer, barrier layer, or gate insulation layer, and in oxide/nitride stacks.

Plasma-enhanced CVD (PECVD) and low-pressure CVD (LPCVD) are the methods primarily used at the present time to form silicon nitride films.

PECVD is typically carried out by introducing a silicon source (typically silane) and a nitrogen source (typically ammonia, but more recently nitrogen) between a pair of parallel plate electrodes and applying high-frequency energy across the electrodes at low temperatures (about 300° C.) and low pressures (0.001 torr to 5 torr) in order to induce the generation of a plasma from the silicon source and nitrogen source. The active silicon species and active nitrogen species in the resulting plasma react with each other to produce a silicon nitride film. The silicon nitride films formed in this manner by PECVD typically do not have a stoichiometric composition and are also hydrogen rich and accordingly exhibit a low film density, a poor step coverage, a fast etching rate, and a poor thermal stability.

LPCVD uses low pressures (0.1 to 2 torr) and high temperatures (800° C. to 900° C.) and produces silicon nitride films with a quality superior to that of the silicon nitride films produced by PECVD. At the present time silicon nitride is typically produced by LPCVD by the reaction of dichlorosilane and gaseous ammonia. However, ammonium chloride is produced as a by-product in the reaction of dichlorosilane and gaseous ammonia in this LPCVD procedure: this ammonium chloride accumulates in and clogs the reactor exhaust lines and also deposits on the wafer. Moreover, existing LPCVD technology suffers from a slow rate of silicon nitride film growth and has a high thermal budget. In order to reduce this thermal budget for the production of silicon nitride films, a method has very recently been developed that produces silicon nitride films by reacting ammonia with hexachlorodisilane used as a silicon nitride precursor. This method, however, suffers from a pronounced exacerbation of the problems cited above due to the large amounts of chlorine present in hexachlorodisilane. Silicon-containing particles are also produced by this method, which results in a substantial reduction in the life of the exhaust lines. Finally, this method can provide high-quality silicon nitride films (good step coverage ratio, low chlorine content) at excellent growth rates at a reaction temperature of, for example, 600° C., but these characteristics suffer from a pronounced deterioration when a reaction temperature ≦550° C. is used.

The use of carbon-containing volatile silazanes, azidosilazanes, and aminosilanes as silicon nitride precursors has been proposed in order to solve the problems cited above (refer, for example, to non-patent references 1 and 2). However, these silicon nitride precursors, whether used by themselves or in combination with ammonia, result in the incorporation of SiC and/or large amounts of carbon in the silicon nitride film product.

(Non-patent reference 1)

Grow et al., Mater. Lett. 23, 187, 1995

(Non-patent reference 2)

Levy et al., J. Mater. Res., 11, 1483, 1996

### PROBLEMS TO BE SOLVED BY THE INVENTION

The problem addressed by this invention, therefore, is to provide a vapor-phase growth method for producing silicon nitride films that can produce silicon nitride films with improved film characteristics and that can do so even at relatively low temperatures, without the accompanying generation of ammonium chloride, and without significant admixture of carbonaceous contaminants into the film product.

### MEANS SOLVING THE PROBLEMS

According to a first aspect of this invention, there is provided a method for producing silicon nitride films by vapor-phase growth, said method being characterized by
feeding a hydrazine gas and at least 1 precursor gas selected from the group consisting of trisilylamine gas and a silylhydrazine gas into a reaction chamber that holds at least 1 substrate and
forming a silicon nitride film on said at least 1 substrate by the reaction of the two gases.

According to a second aspect of this invention, there is provided a method for producing silicon nitride films by vapor-phase growth, said method being characterized by
feeding a silylhydrazine gas into a reaction chamber that holds at least 1 substrate and
forming a silicon nitride film on said at least 1 substrate by the decomposition of said silylhydrazine gas.

This invention is explained more specifically hereinbelow.

This invention, which relates to methods for forming silicon nitride films on substrates by a vapor-phase growth procedure such as CVD, employs trisilylamine ((H₃Si)₃N) and/or a silylhydrazine as silicon nitride precursors. These precursors produce a silicon nitride film by a vapor-phase reaction with a hydrazine. Among these precursors, the silylhydrazine can form a silicon nitride film by itself by thermal decomposition.

The silylhydrazine used by this invention encompasses silylhydrazine as defined by formula (I)
H₃Si(R^{a})N—N(R^{b})R^{c} (I)
wherein R^{a}, R^{b}, and R^{c} are each independently selected from silyl, the hydrogen atom, methyl, ethyl, and phenyl.

The hydrazine that is reacted with the aforementioned precursors encompasses hydrazines defined by formula (II)
H(R¹)N—N(R²)R³ (II)
wherein R¹, R², and R³ are each independently selected from the hydrogen atom, methyl, ethyl, and phenyl.

The method for producing silicon nitride film by reacting a hydrazine with the aforementioned precursors (CVD procedure) will be described first. In this case, a precursor gas, a hydrazine gas, and optionally an inert dilution gas are fed into a reaction chamber that holds at least one substrate (particularly a semiconductor substrate such as a silicon substrate) and a silicon nitride film is formed on the substrate(s) by reaction between the precursor gas and hydrazine gas.

The interior of the reaction chamber can be maintained at a pressure from 0.1 torr to 1,000 torr during the reaction between the precursor gas and hydrazine gas, while maintenance of a pressure of 0.1 torr to 10 torr within the reaction chamber is preferred.

The reaction between the precursor gas and hydrazine gas can generally be carried out at temperatures (CVD reaction temperature) no greater than 1,000° C. However, almost no production of silicon nitride occurs at temperatures below 300° C. Accordingly, the reaction between precursor gas and hydrazine gas can generally be carried out at 300° C. to 1,000° C. This precursor and the hydrazine can produce silicon nitride at sufficiently high growth rates (film formation rate) even at low temperatures of 400° C. to 700° C. In addition, when the CVD reaction temperature is 300° C. to 500° C., step coverage ratios, for example, of at least about 0.8 can be achieved even for apertures with an aspect ratio of 10. The step coverage ratio can be defined as the value afforded by dividing the minimum film thickness at a step feature by the film thickness in a flat or planar region. The CVD reaction temperature is usually the temperature of or near the substrate on which the silicon nitride is formed.

The hydrazine gas and precursor gas can be fed into the reaction chamber at a hydrazine/precursor flow rate ratio generally of no more than 100. While silicon nitride can be produced even when the hydrazine/precursor flow rate ratio exceeds 100, hydrazine/precursor flow rate ratios in excess of 100 are generally uneconomical. Preferred values of the hydrazine/precursor flow rate ratio are from 1 to 80.

The inert dilution gas introduced on an optional basis into the reaction chamber can be an inert gas, for example, nitrogen or a rare gas such as argon.

Since neither the precursor nor the hydrazine used by this invention contains chlorine, their reaction does not generate the ammonium chloride by-product that has heretofore been a problem. Moreover, while the silylhydrazine and/or hydrazine used by this invention includes species that contain carbon, a relatively low carbon concentration in the silicon nitride product has been confirmed even for the use of such carbon-containing species.

The production of silicon nitride films by the use of silylhydrazine by itself and its thermal decomposition will now be considered. In this case, silylhydrazine gas is introduced into the reaction chamber, along with any inert dilution gas used on an optional basis, and a silicon nitride film is produced by thermal decomposition of the silylhydrazine. As in the CVD procedure considered above, the pressure in the reaction chamber can be maintained at from 0.1 torr to 1,000 torr, while the pressure in the reaction chamber is preferably maintained at from 0.1 torr to 10 torr.

As with the CVD procedure considered above, decomposition of the silylhydrazine gas can generally be carried out at temperatures from 300° C. to 1,000° C. This silylhydrazine decomposition can produce silicon nitride at sufficiently high growth rates (film formation rate) even at low temperatures of 400° C. to 700° C. In addition, high step coverage ratios can be achieved when the decomposition temperature is 300° C. to 500° C.

For both the CVD procedure and the thermal decomposition procedure, the silylhydrazine gas can be prepared in advance and stored in a sealed container until use or can be synthesized onsite and the gaseous reaction mixture containing the synthesized silylhydrazine gas can be introduced into the reaction chamber. A silylamine gas and a hydrazine gas are introduced into a synthesis chamber in order to effect this onsite synthesis of silylhydrazine gas. At this point, an inert dilution gas, such as the inert dilution gas that may be introduced into the reaction chamber as discussed above, can also be introduced into the synthesis chamber along with the aforementioned reaction gases. With regard to the conditions during introduction of the silylamine gas and hydrazine gas into the synthesis chamber, the pressure in the synthesis chamber should be maintained at 0.1 to 1,000 torr and the hydrazine gas/silylamine gas flow rate ratio should be 10 to 1,000. The two gases can be reacted at temperatures ranging from room temperature to 500° C. Silylhydrazine is produced by this reaction. The resulting silylhydrazine-containing gaseous reaction mixture within the synthesis chamber can then be subjected to pressure adjustment by a pressure regulator and introduced into the above-described reaction chamber. The silylamine used here encompasses silylamine defined by formula (III)
(H₃Si)ₘN(H)₃₋ₘ (III)
wherein m is an integer from 1 to 3. The hydrazine introduced into the synthesis chamber encompasses hydrazine defined by formula (IV)
H(R^{x})N—N(R^{y})R^{z} (IV)
wherein R^{x}, R^{y}, and R^{z} are each independently selected from the hydrogen atom, methyl, ethyl, and phenyl.

Silylhydrazine (I), for example, can be produced by the reaction of the silylamine (III) and hydrazine (IV).

FIG. 1 contains a block diagram of one example of a CVD-based apparatus for producing silicon nitride films that is well-suited for executing the inventive method for producing silicon nitride films. The apparatus illustrated in Example 1 uses a precursor gas source that contains already prepared precursor gas.

The production apparatus 10 illustrated in FIG. 1 is provided with a reaction chamber 11, a precursor gas source 12, a hydrazine gas source 13, and a source 14 of inert dilution gas that may be introduced as circumstances dictate.

A susceptor 111 is disposed within the reaction chamber 11, and a semiconductor substrate 112, such as a silicon substrate, is mounted on the susceptor 111 (a single semiconductor substrate is mounted on the susceptor 111 since the apparatus illustrated in FIG. 1 is a single-wafer apparatus). A heater 113 is provided within the susceptor 111 in order to heat the semiconductor substrate 112 to the prescribed CVD reaction temperature. From several semiconductor substrates to 250 semiconductor substrates may be held in the reaction chamber in the case of a batch apparatus. The heater used in a batch apparatus can have a different structure from the heater used in a single-wafer apparatus.

The precursor gas source 12 comprises a sealed container that holds liquefied precursor. The precursor gas is introduced from its source 12 through the precursor gas feed line L1 and into the reaction chamber 11. There are disposed in this line L1 a shut-off valve V1 for the precursor gas source 12 and, downstream from said shut-off valve V1, a flow rate controller such as, for example, a mass flow controller MFC1. The precursor gas is subjected to control to a prescribed flow rate by the mass flow controller MFC1 and is introduced into the reaction chamber 11.

The hydrazine gas source 13 comprises a sealed container that holds liquefied hydrazine. The hydrazine gas is introduced from its source 13 through the hydrazine gas feed line L2 and into the reaction chamber 11. There are disposed in this line L2 a shut-off valve V2 and, downstream therefrom, a flow rate controller such as, for example, a mass flow controller MFC2. The hydrazine gas is subjected to control to a prescribed flow rate by the mass flow controller MFC2 and is introduced into the reaction chamber 11.

The inert dilution gas source 14 comprises a sealed container that holds the inert dilution gas. As necessary or desired, the inert dilution gas is introduced from its source 14 and into the reaction chamber 11 through the inert dilution gas feed line L3. As shown in FIG. 1, the inert dilution gas feed line L3 can be joined with the precursor gas feed line L1 and the inert dilution gas can thereby be introduced into the reaction chamber 11 in combination with the precursor gas. There are disposed in this line L3 a shut-off valve V3 and, downstream therefrom, a flow rate controller such as, for example, a mass flow controller MFC3. The inert gas is subjected to control to a prescribed flow rate by the mass flow controller MFC3 and is introduced into the reaction chamber 11.

The outlet from the reaction chamber 11 is connected to a waste gas treatment facility 15 by the line L4. This waste gas treatment facility 15 removes, for example, the by-products and unreacted material, and the gas purified by the waste gas treatment facility 15 is discharged from the system. There are disposed in the line L4 a pressure sensor PG, a pressure regulator such as a butterfly valve BV1, and a vacuum pump PM. The introduction of each gas into the reaction chamber 11 is carried out by the respective mass flow controllers, while the pressure within the reaction chamber 11 is monitored by the pressure sensor PG and is established at a prescribed pressure value by operation of the pump PM and control of the aperture of the butterfly valve BV1.

When the silicon nitride film is to be produced by thermal decomposition of the silylhydrazine gas, use of the hydrazine feed system (the source 13, feed line L2, shut-off valve V2, and mass flow controller MFC2) becomes unnecessary and it need not be provided.

FIG. 2 contains a block diagram that illustrates an apparatus for producing silicon nitride films that contains an onsite facility for producing silylhydrazine. Those constituent elements in FIG. 2 that are the same as in FIG. 1 are assigned the same reference symbol and their detailed explanation has been omitted.

The production apparatus 20 illustrated in FIG. 2, in addition to having the same type of reaction chamber 11 as the one illustrated in FIG. 1, contains a synthesis chamber 21 for the onsite synthesis of silylhydrazine. A heater 211 is disposed on the circumference of this synthesis chamber 21 for the purpose of heating the interior of the synthesis chamber 21 to the prescribed reaction temperature.

The production apparatus 20 illustrated in FIG. 2 lacks the precursor gas source 12 shown in FIG. 1 and contains a source 22 of a silylamine that will react with the hydrazine to produce a silylhydrazine. The silylamine source 22 comprises a sealed container that holds the silylamine in liquid form. Silylamine gas is introduced from this source 22 through the feed line L21 and into the synthesis chamber 21. There are disposed in the line L21 a shut-off valve V21 and, downstream therefrom, a flow rate controller such as, for example, a mass flow controller MFC21. The silylamine gas is subjected to control to a prescribed flow rate by the mass flow controller MFC21 and is introduced into the synthesis chamber 21.

The hydrazine gas source 13 is provided with a feed line L22 to the synthesis chamber 21 in addition to the feed line L2 to the reaction chamber 11. There are disposed in this feed line L22 a shut-off valve V22 and, downstream therefrom, a flow rate controller such as, for example, a mass flow controller MFC22. The hydrazine gas is subjected to control to a prescribed flow rate by the mass flow controller MFC22 and is introduced into the synthesis chamber 21.

The inert dilution gas source 14 is provided with a feed line L23 to the synthesis chamber 21 in addition to the feed line L3 to the reaction chamber 11. There are disposed in this feed line L23 a shut-off valve V23 and, downstream therefrom, a flow rate controller such as, for example, a mass flow controller MFC23. As necessary or desired, the inert dilution gas is subjected to control to a prescribed flow rate by the mass flow controller MFC23 and is introduced into the synthesis chamber 21. The line L3 in the apparatus in FIG. 2 is directly connected to the reaction chamber 11.

The outlet from the synthesis chamber 21 is connected by the line L24 to the reaction chamber 11. A pressure regulator, for example, a butterfly valve BV2, is provided in the line L24. The silylhydrazine gas-containing gaseous reaction mixture afforded by the synthesis chamber 21 is introduced into the reaction chamber 11 after the pressure in the synthesis chamber 21 has been adjusted by the butterfly valve BV2 as appropriate for introduction into the reaction chamber 11.

With regard to the handling of the precursor gas in the apparatus illustrated in FIG. 1 for producing silicon nitride films, the gas-phase material is withdrawn from the precursor gas source 12—which holds the precursor gas in liquid form—and is introduced into the reaction chamber 11 via the line L1 by opening the valve V1 and carrying out adjustment using the mass flow controller MFC1. However, the precursor gas can also be introduced into the reaction chamber 11 through the line L1 using a bubbler or vaporizer. FIG. 3 illustrates a precursor gas feed system that uses a bubbler. This feed system, which is used in place of the precursor gas source 12 and the valve V1 in the production apparatus illustrated in FIG. 1, is provided with a precursor gas source 32 that holds precursor gas 31 in liquid form. The line L31 is inserted into this precursor gas source 32 in order to bubble inert gas from a source 33 of the same inert gas as described above into the liquid precursor gas 31 held in the precursor gas source 32. A shut-off valve V31 is disposed in the line L31. The line L1 shown in the production apparatus of FIG. 1 is inserted into the precursor gas source 32 above the liquid surface of the liquid precursor gas 31. A shut-off valve V32 is disposed in the line L1. Precursor becomes entrained in the inert gas when the inert gas is bubbled thereinto and is introduced into the reaction chamber 11 shown in FIG. 1 through the line L1 while being subjected to flow rate control by the mass flow controller MFC1.

FIG. 4 illustrates a precursor gas feed system that uses a vaporizer. This feed system, which is used in place of the precursor gas source 12 and the mass flow controller MFC1 in the production apparatus illustrated in FIG. 1, is provided with a precursor gas source 42 that holds precursor gas 41 in liquid form. A line L41 is provided to this precursor gas source 42 in order to introduce inert gas from a source 43 of the same inert gas as described above, in such a manner that the liquid surface of the liquid precursor gas 31 is pressed by the inert gas. A shut-off valve V41 is disposed in the line L41. In addition, the line L1 in the production apparatus illustrated in FIG. 1 is inserted into the precursor gas source 42 into the liquid precursor gas 41 itself. There are provided in this line L1 a shut-off valve V42, a liquid mass flow controller LMFC41 downstream therefrom, and a vaporizer 44 downstream from the liquid mass flow controller LMFC41. The liquid precursor 41 pressed out by the introduction of inert gas from the inert gas source 43 flows through the line L1 and is subjected to flow rate control by the liquid mass flow controller LMFC41 and is introduced into the vaporizer 44. The liquid precursor is vaporized in this vaporizer 44 and is then introduced into the reaction chamber 11 shown in FIG. 1. Inert gas can also be introduced into the vaporizer 44 through the line L42 from the inert gas source 45 in order to promote vaporization of the liquid precursor in the vaporizer 44. There are disposed in this line L42, for example, a mass flow controller MFC42 in order to control the flow rate of inert gas from the inert gas source 45 and, downstream from said mass flow controller MFC42, a shut-off valve V43.

### EXAMPLES

This invention will be described in additional detail by working examples as follows, but this invention is not limited to these working examples.

### Example 1

This example used a production apparatus with the structure illustrated in Example 1. Silicon nitride films were produced on silicon substrates at different CVD reaction temperatures (T) while introducing TSA gas at a feed flow rate of 0.5 sccm or 4 sccm and 1,1-dimethylhydrazine (UDMH) gas at a feed flow rate of 40 sccm into a reaction chamber that held a silicon substrate. The pressure within the reaction chamber was maintained at 1 torr. The silicon nitride deposition (growth) rate was measured during this process, and the obtained values are plotted logarithmically in FIG. 5 against 1,000 times the reciprocal of the reaction temperature (T in K). Line a in FIG. 5 plots the results for the feed of 0.5 sccm TSA gas (UDMH/TSA feed flow rate ratio=80), while line b plots the results for a TSA gas feed of 4 sccm (UDMH/TSA feed flow rate ratio=10).

As may be understood from the results in FIG. 5, the silicon nitride film growth rate was larger at the smaller UDMH/TSA feed flow rate ratio and increased with increasing reaction temperature. However, the silicon nitride film growth rate was still high enough for practical applications even at a temperature as low as 480° C.

The composition of the obtained silicon nitride films as measured by Auger elemental analysis and ellipsometry was Si_{0.8-0.9}N. The carbon content of the silicon nitride films prepared at a UDMH/TSA feed flow rate ratio of 80 was only 3 weight %. The etching rate of the individual silicon nitride films by 0.25% aqueous hydrogen fluoride was measured at 30-50 Å/min in all cases, which is substantially lower than the etching rate of silicon nitride films afforded by PECVD.

The gaseous reaction mixture within the reaction chamber was also analyzed by Fourier transform infrared spectroscopy (FTIR) in this example. It was confirmed at both UDMH/TSA feed flow rate ratios that (a) the intensity ratio (l(947)/l(2172)) for the two main peaks for TSA (the peak at about 947 cm⁻¹ assigned to the SiN bond and the peak at about 2172 cm⁻¹ assigned to the SiH bond) underwent a change (see FIG. 6) and (b) the peak assigned to the SiH bond shifted from 2172 cm⁻¹ to 2163 cm⁻¹. These facts confirm that disilyidimethylhydrazine (SiH₃)₂N—N(CH₃)₂ was produced by the reaction of TSA and UDMH at temperatures ≧450° C. (see FIG. 6). The correlation and synthesis of the facts associated with the production of silicon nitride films in this example enables the following to be said:
(i) silylhydrazine can be used as precursor;
(ii) silylhydrazine can be produced by the reaction of a silylamine and a hydrazine; and
(iii) silicon nitride can be produced using the silylhydrazine-containing gaseous reaction mixture produced by the reaction of a silylamine and a hydrazine.

### Example 2

Using a production apparatus with the structure shown in FIG. 1, silicon nitride films were formed at different reaction temperatures in a reaction chamber holding a silicon substrate on which trenches (diameter: 0.6 μm) with an aspect ratio (depth/diameter) of 10 had been formed. UDMH was introduced at a flow rate of 40 sccm; TSA gas was introduced at a flow rate of 4 sccm; and a pressure of 1 torr was established in the reaction chamber. The step coverage ratios of the silicon nitride films obtained at the different temperatures were measured by scanning electron microscopy (SEM), and the results are reported in FIG. 7.

The results reported in FIG. 7 not only show that the step coverage ratio of the silicon nitride film product can be improved to about 0.8 by establishing the reaction temperature at 500° C., but also enable the prediction that the step coverage ratio can be improved still further by setting the reaction temperature at even lower values.

This invention has been described hereinabove through various embodiments and working examples, but this invention is not limited thereto. The various embodiments described above can be combined.

As has been described hereinabove, the inventive methods are not accompanied by the production of ammonium chloride, avoid significant admixture of carbonaceous contaminants in the film products, and also enable the production of silicon nitride films with better film properties even at relatively low temperatures.

### BRIEF DESCRIPTION OF THE DRAWINGS

FIG. 1 contains a block diagram that illustrates an example of an apparatus for producing silicon nitride films.

FIG. 2 contains a block diagram that illustrates another example of an Apparatus for producing silicon nitride films.

FIG. 3 contains a block diagram of a precursor gas feed system that uses a bubbler.

FIG. 4 contains a block diagram of a precursor gas feed system that uses a vaporizer.

FIG. 5 contains a graph that shows the relationship between the CVD reaction temperature and the silicon nitride film growth rate.

FIG. 6 contains a graph that shows the relationship between the intensity ratio between the two main peaks for TSA and the reaction temperature.

FIG. 7 contains a graph that shows the relationship between the CVD reaction temperature and the step coverage ratio for silicon nitride films.

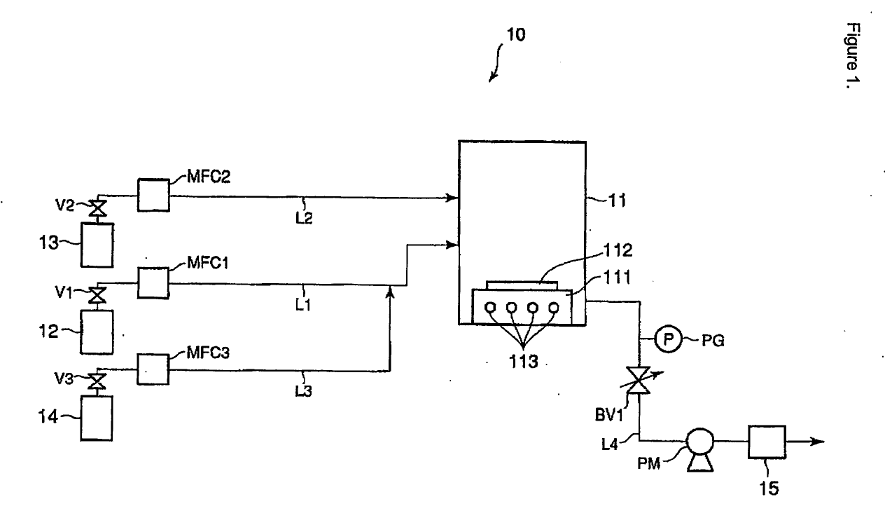

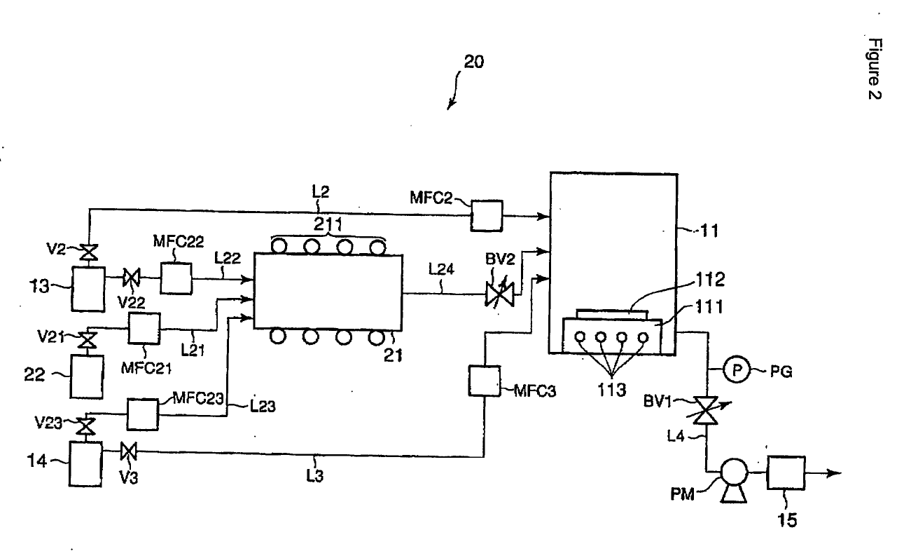

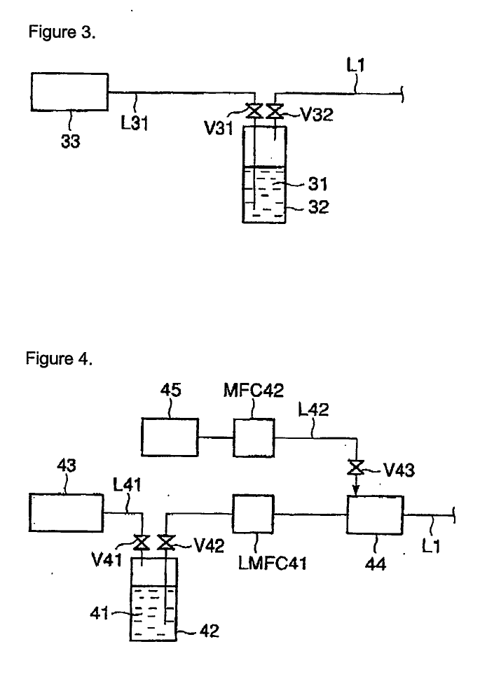

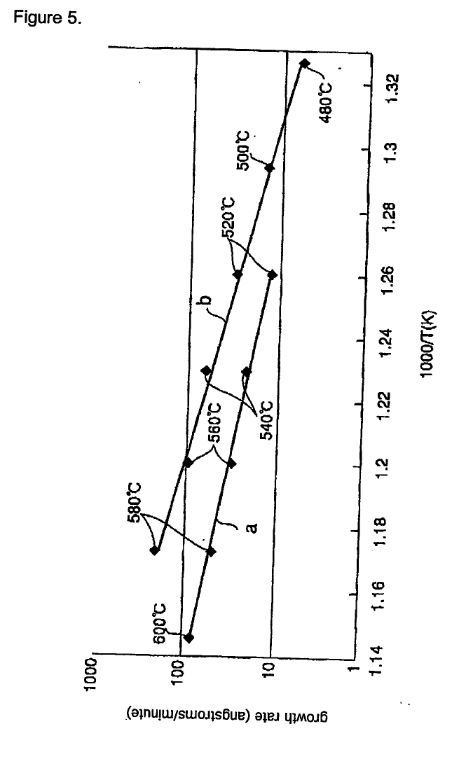

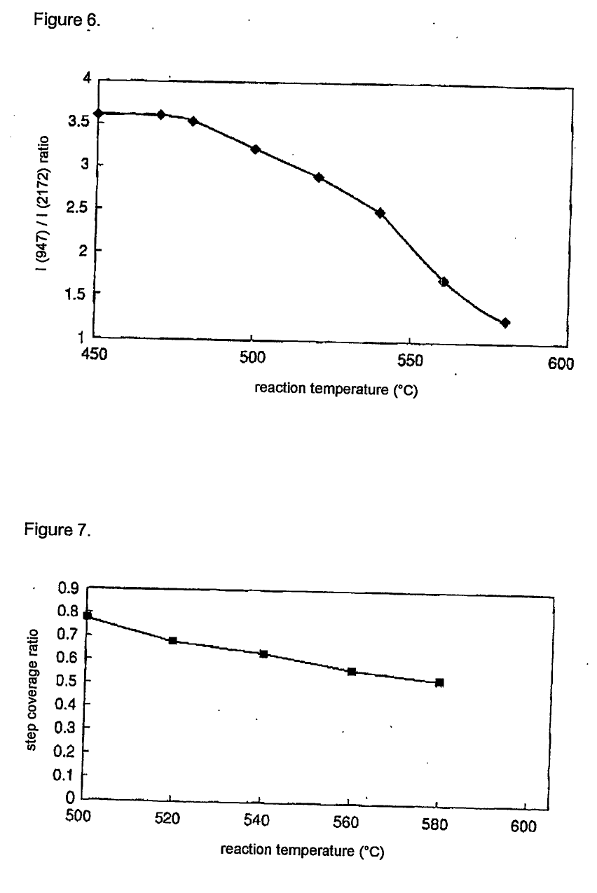

1-17. (canceled)

18. A method which may be used for producing a silicon nitride film by vapor-phase growth, wherein said method comprises:
a) feeding a first hydrazine gas and at least one precursor gas into a reaction chamber, wherein:
1) said precursor gas comprises at least one member selected from the group consisting of:
i) trisilylamine gas; and
ii) silylhydrazine gas; and
2) at least one substrate is located in said reaction chamber; and
b) forming a silicon nitride film on said substrate by reacting said first hydrazine gas and said precursor gas.

19. The method of claim 18, wherein:
a) said silylhydrazine is defined by formula (I)
H₃Si(R^{a})N—N(R^{b})R^{c} (I); and
b) R^{a}, R^{b}, and R^{c} each comprise at least one member selected from the group consisting of:
1) silyl;
2) hydrogen;
3) methyl;
4) ethyl; and
5) phenyl.

20. The method of claim 18, further comprising:
a) creating said precursor gas in a synthesis chamber by reacting a silylamine gas with a second hydrazine gas to form a silylhydrazine gas; and
b) feeding said precursor gas into said reaction chamber from said synthesis chamber.

21. The method of claim 18, wherein:
a) said first hydrazine gas is defined by formula (II)
H(R¹)N—N(R²)R³ (II); and
b) R¹, R², and R³ each comprise at least one member selected from the group consisting of:
1) hydrogen;
2) methyl;
3) ethyl; and
4) phenyl.

22. The method of claim 20, wherein:
a) said silylamine is defined by formula (III)
(H₃Si)ₘN(H)₃₋ₘ (III); and
b) m is 1, 2, or 3.

23. The method of claim 20, wherein:
a) said second hydrazine is defined by formula (IV)
H(R^{x})N—N(R^{y})R^{z} (IV); and
b) R^{x}, R^{y}, and R^{z} each comprise at least one member selected from the group consisting of:
1) hydrogen;
2) methyl;
3) ethyl; and
4) phenyl.

24. The method of claim 18, wherein the temperature of the reaction between said precursor gas and said first hydrazine gas is between about 300° C. and about 700° C.

25. The method of claim 18, wherein the pressure in said reaction chamber is between about 0.1 torr and about 1000 torr.

26. The method of claim 18, further comprising feeding an inert dilution gas into said reaction chamber.

27. A method which may be used for producing silicon nitride films by vapor-phase growth, said method comprising:
a) feeding a silylhydrazine gas into a reaction chamber, wherein said chamber contains at least one substrate; and
b) forming a silicon nitride film on said substrate by a decomposition of said silylhydrazine gas.

28. The method of claim 27, wherein:
a) said silylhydrazine is defined by formula (I)
H₃Si(R^{a})N—N(R^{b})R^{c} (I); and
b) R^{a}, R^{b}, and R^{c} each comprise at least one member selected from the group consisting of:
1) silyl;
2) hydrogen;
3) methyl;
4) ethyl; and
5) phenyl.

29. The method of claim 27, further comprising
a) creating a silylhydrazine-containing reaction mixture in a synthesis chamber by reacting a silylamine gas with a hydrazine gas; and
b) feeding said silylhydrazine-containing reaction mixture into said reaction chamber.

30. The method of claim 29, wherein:
a) said hydrazine is defined by formula (IV)
H(R^{x})N—N(R^{y})R^{z} (IV); and
b) R^{x}, R^{y}, and R^{z} each comprise at least one member selected from the group consisting of:
1) hydrogen;
2) methyl;
3) ethyl; and
4) phenyl.

31. The method of claim 29, wherein:
a) said silylamine is defined by formula (III)
(H₃Si)ₘN(H)₃₋ₘ (III) and
b) m is 1, 2, or 3.

32. The method of claim 27, wherein the decomposition of said silylhydrazine gas is carried out at a temperature between about 300° C. and about 700° C.

33. The method of claim 27, wherein the pressure in said reaction chamber is between about 0.1 torr and about 1000 torr.

34. The method of claim 27, further comprising feeding an inert dilution gas into said reaction chamber.

35. A method which may be used for producing a silicon nitride film by vapor-phase growth, wherein said method comprises:
a) feeding a first hydrazine gas and at least one precursor gas into a reaction chamber, wherein:
1) said precursor gas comprises at least one member selected from the group consisting of:
i) trisilylamine gas; and
ii) silylhydrazine gas;
2) at least one substrate is located in said reaction chamber; and
3) the pressure in said reaction chamber is between about 0.1 torr and about 1000 torr; and
b) feeding an inert dilution gas into said reaction chamber; and
c) forming a silicon nitride film on said substrate by reacting said first hydrazine gas and said precursor gas, wherein the temperature of the reaction is between about 300° C. and about 700° C.
